(19) United States
(12) Patent Application Publication
(10) Pub. No.: US 2024/0319297 A1
(43) Pub. Date: Sep. 26, 2024

(54) Method and Apparatus for Monitoring Operating State of Birdcage Coil in Magnetic Resonance System

(71) Applicant: Siemens Healthineers AG, Forchheim (DE)

(72) Inventors: Jun Zhang, Shenzhen (CN); Ying Lun Wang, Shenzhen (CN)

(73) Assignee: Siemens Healthineers AG, Forchheim (DE)

(21) Appl. No.: 18/610,885

(22) Filed: Mar. 20, 2024

(30) Foreign Application Priority Data
Mar. 21, 2023 (CN) 202310306448.5

(51) Int. Cl. G01R 33/34

(52) U.S. Cl. CPC G01R 33/34076

(57) ABSTRACT

The present disclosure relates to techniques for monitoring an operating state of a birdcage coil in a magnetic resonance system. The birdcage coil comprises a pair of end rings, and multiple legs arranged between the pair of end rings and connected to the pair of end rings. The technique enables a determination that an open circuit has occurred in at least one of the multiple legs.

### CROSS-REFERENCE TO RELATED APPLICATIONS

The present application claims priority to and the benefit of China Patent Application no. CN 202310306448.5, filed Mar. 21, 2023, the contents of which are incorporated herein by reference in their entirety.

### TECHNICAL FIELD

The present disclosure relates to the technical field of magnetic resonance and, in particular, to a method and apparatus for monitoring an operating state of a birdcage coil in a magnetic resonance system, an electronic device, a magnetic resonance system, a birdcage coil for a magnetic resonance system, and a computer program product.

### BACKGROUND

Magnetic resonance imaging (MRI) technology plays an important role in medical diagnosis. MRI uses the principle of nuclear magnetic resonance. That is, based on differences in the attenuation of released energy in different structural environments within a substance, by applying a gradient magnetic field externally to detect emitted electromagnetic waves, the positions and types of atomic nuclei forming the object can be ascertained, and on this basis, a structural image of the interior of the object can be drawn.

The method described in this section is not necessarily a previously envisaged or used method. Unless otherwise stated, it should not be assumed that any method described in this section is regarded as prior art simply because it is included in this section. Similarly, unless otherwise stated, problems mentioned in this section should not be regarded as having been generally acknowledged in any prior art.

### SUMMARY

According to one aspect of embodiments of the present disclosure, a method for monitoring an operating state of a birdcage coil in a magnetic resonance system is proposed. The birdcage coil comprises a pair of end rings, and multiple legs arranged between the pair of end rings and connected to the pair of end rings. The method comprises: acquiring a first parameter, the first parameter being associated with a voltage at a first position of a first end ring in the pair of end rings; acquiring a second parameter, the second parameter being associated with a voltage at a second position of the first end ring, the second position being different from the first position; based on the first parameter and the second parameter, determining a right-handed circularly polarized component and a left-handed circularly polarized component of a magnetic resonance RF field of the birdcage coil; determining the absolute value of the ratio of the left-handed circularly polarized component to the right-handed circularly polarized component; and in response to determining that the absolute value of the ratio exceeds a threshold, determining that an open circuit has occurred in at least one of the multiple legs.

According to another aspect of embodiments of the present disclosure, an apparatus for monitoring an operating state of a birdcage coil in a magnetic resonance system is proposed. The birdcage coil comprises a pair of end rings, and multiple legs arranged between the pair of end rings and connected to the pair of end rings. The apparatus comprises: a first parameter acquisition unit, configured to acquire a first parameter, the first parameter being associated with a voltage at a first position of a first end ring in the pair of end rings; a second parameter acquisition unit, configured to acquire a second parameter, the second parameter being associated with a voltage at a second position of the first end ring, the second position being different from the first position; a magnetic resonance RF field determining unit, configured to determine, on the basis of the first parameter and the second parameter, a right-handed circularly polarized component and a left-handed circularly polarized component of a magnetic resonance RF field of the birdcage coil; a ratio determining unit, configured to determine the absolute value of the ratio of the left-handed circularly polarized component to the right-handed circularly polarized component; and an open circuit determining unit, configured to determine, in response to determining that the absolute value of the ratio exceeds a threshold, that an open circuit has occurred in at least one of the multiple legs.

According to another aspect of embodiments of the present disclosure, an electronic device is proposed, comprising: at least one processor; and a memory in communicative connection with the at least one processor. The memory stores instructions which are executable by the at least one processor; the instructions are executed by the at least one processor, to enable the at least one processor to perform the method for monitoring an operating state of a birdcage coil in a magnetic resonance system according to an embodiment of the present disclosure.

According to another aspect of embodiments of the present disclosure, a magnetic resonance system is proposed, comprising: a birdcage coil, comprising a pair of end rings, and multiple legs arranged between the pair of end rings and connected to the pair of end rings; and the apparatus for monitoring an operating state of a birdcage coil in a magnetic resonance system according to an embodiment of the present disclosure or the electronic device according to an embodiment of the present disclosure.

According to another aspect of embodiments of the present disclosure, a birdcage coil for a magnetic resonance system is proposed, the birdcage coil comprising: a pair of end rings, and multiple legs arranged between the pair of end rings and connected to the pair of end rings; a first contactless probe arranged close to a first capacitor on a first end ring in the pair of end rings, for generating a first induced voltage under the action of the first capacitor; and a second contactless probe arranged close to a second capacitor on the first end ring, for generating a second induced voltage under the action of the second capacitor.

According to another aspect of embodiments of the present disclosure, a computer program product is proposed, comprising a computer program, wherein the computer program, when executed by a processor, realizes the method for monitoring an operating state of a birdcage coil in a magnetic resonance system according to an embodiment of the present disclosure.

It should be understood that the content described in this section is not intended to identify key or important features of embodiments of the present disclosure, and not intended to limit the scope of the present disclosure. Other features of the present disclosure will become easy to understand through the following description.

### BRIEF DESCRIPTION OF THE DRAWINGS

The drawings show embodiments demonstratively and form part of this specification, being used together with the textual description of this specification to explain exemplary ways of implementing embodiments. The embodiments shown merely serve an illustrative purpose, and do not limit the scope of the claims. In all of the drawings, identical reference labels denote similar but not necessarily identical key elements.

Embodiments of the present disclosure are described in detail below with reference to the accompanying drawings, to give those skilled in the art a clearer understanding of the abovementioned and other features and advantages of the present disclosure. In the drawings:

FIGS. 1A and 1B illustrate a magnetic field strength map obtained by subjecting an RF coil to simulated calculation;

FIGS. 2A and 2B illustrate an electric field strength map obtained by subjecting an RF coil to simulated calculation;

FIG. 3 illustrates a schematic drawing of an example birdcage coil in a magnetic resonance system, according to an embodiment of the present disclosure;

FIG. 4 illustrates a flow chart of an example method for monitoring an operating state of a birdcage coil in a magnetic resonance system, according to an embodiment of the present disclosure;

FIG. 5 illustrates a structural block diagram of an example apparatus for monitoring an operating state of a birdcage coil in a magnetic resonance system, according to an embodiment of the present disclosure; and

FIG. 6 illustrates a block diagram showing an example electronic device, according to an embodiment of the present disclosure.

### DETAILED DESCRIPTION OF THE DISCLOSURE

Demonstrative embodiments of the present disclosure are described below with reference to the drawings, including various details of embodiments of the present disclosure to assist understanding, but these should be regarded as merely demonstrative. Thus, those skilled in the art should recognize that various changes and modifications could be made to the embodiments described here without deviating from the scope of the present disclosure. Similarly, for clarity and conciseness, descriptions of commonly known functions and structures are omitted in the descriptions below.

In the present disclosure, unless otherwise stated, the use of the terms “first”, “second”, etc. to describe various key elements is not intended to define a positional relationship, time sequence relationship or importance relationship between these key elements; such terms are merely used to distinguish one element from another. In some examples, a first key element and a second key element may refer to the same instance of the element in question, whereas in some cases, based on the description in the context, they may also denote different instances.

Terms used in the descriptions of the various examples in the present disclosure are merely intended to describe specific examples, and are not intended to impose restrictions. Unless clearly indicated otherwise in the context, if the quantity of a key element is not specifically defined, the key element may be one or more. In addition, the term “and/or” used in the present disclosure covers any one of the listed items and all possible combinations.

A magnetic resonance system comprises a main magnet, a gradient system, an RF system, and a computer system. The RF system is a relatively important part of a magnetic resonance device, the main function thereof being to execute RF excitation and receive nuclear magnetic resonance signals. The RF system of a nuclear magnetic resonance device may comprise an RF transmission unit, an RF coil, an RF receiving unit, etc.

The function of the RF transmission unit is to provide various RF pulses required for a scanning sequence under the action of an RF controller, continuously adjusting the amplitude of a magnetic resonance RF field in an RF transmission circuit so as to change the RF pulse flip angle. The RF transmission unit mainly comprises an RF transmission controller, an RF pulse sequence generator, an RF pulse generator, an RF oscillator (RF pulse source), an RF synthesizer, a filtering amplifier, a waveform modulator, an RF power amplifier, a transmission terminal matching circuit, an RF transmission coil, etc.

An RF coil can act as both a source of excitation for magnetic resonance of atomic nuclei, and a detector for magnetic resonance signals. Among RF coils, coils used to establish an RF field are called transmit coils, and coils used to detect magnetic resonance signals are called receive coils. Some coils can serve a double function of transmitting RF and receiving signals; for example, a body coil in an magnetic resonance system can be used to excite resonance in an examination subject, and also to collect magnetic resonance signals. In addition, some coils are only used as signal receiving coils; most coils used for various examination regions in clinical medical examination (e.g. surface coils) are coils that are only able to receive magnetic resonance signals. When such coils are used, RF excitation is mainly performed by the body coil in the system.

The function of the RF receiving unit is to receive magnetic resonance signals generated by the human body, and transmit them to a data collection unit after a series of processing operations such as amplification, mixing, filtering, detection, and analog/digital conversion. The RF receiving unit comprises a receive coil, a preamplifier, a mixer, a phase-sensitive detector, a low-pass filter and an analog/digital converter, etc.

In the process of MRI, the RF system can generate a digital pulse waveform according to a pulse sequence selected by a user; the digital pulse waveform can be converted to an analog signal by a digital-to-analog converter, and the analog signal can drive the transmit coil after modulation and amplification for the purpose of exciting resonance in atomic nuclei in an imaging region so as to generate a nuclear magnetic resonance signal. The weak nuclear magnetic resonance signal is amplified by the preamplifier, then undergoes demodulation, filtering, analog/digital conversion, preprocessing, Fourier transformation, etc., so as to reconstruct a nuclear magnetic resonance image.

The use of magnetic resonance imaging for medical examination is a clinically important imaging examination method; the principle thereof to use the phenomenon of magnetic resonance to image tissue of a region to be examined in the human body so as to assess the form of the tissue, and to judge whether a pathological change has occurred. As stated above, RF energy will be generated as an magnetic resonance examination is conducted. This RF energy may be converted to thermal energy after absorption by the human body, and this thermal energy will promote an increase in body temperature. The specific absorption rate (SAR) for RF energy generally refers to the RF energy absorbed per unit of biological tissue, and can be used to assess the thermal energy absorbed by the examination subject during a magnetic resonance examination. The higher the value of the RF energy SAR, the greater the amount of thermal energy accumulated in the human body due to RF energy. When the RF energy SAR is too high, this might lead to an abnormal increase in body temperature, and thereby damage the health. Thus, the RF energy SAR should generally be kept within a safe range.

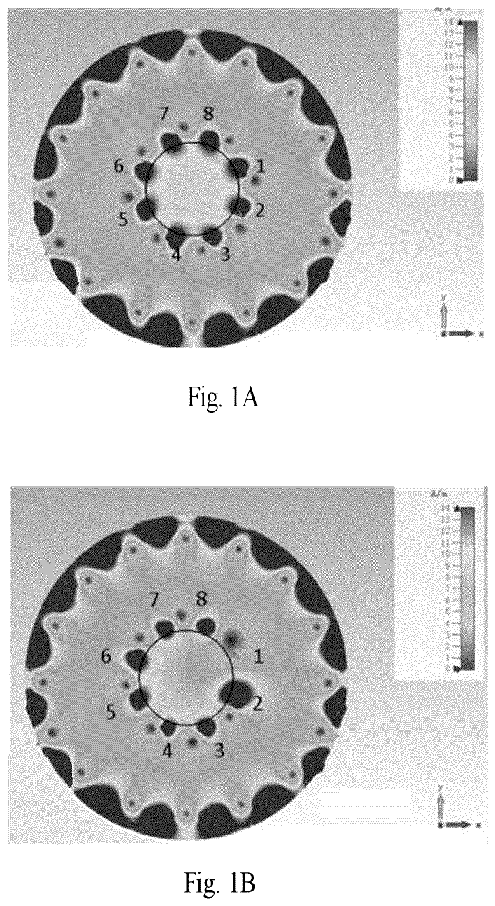

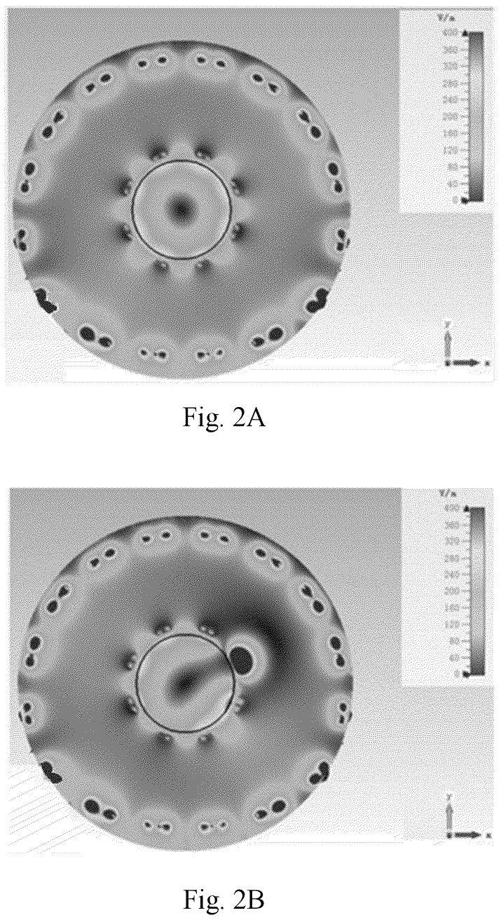

In the related art, if the RF coil develops a fault during operation, this might have an adverse impact on the result of magnetic resonance imaging, and might also damage the health of the examination subject. For example, in some magnetic resonance systems, fusible devices (e.g. fuses) for circuit protection are provided on legs of the birdcage RF coil; when the current in one of the legs exceeds a permitted value for the corresponding fusible device, the fusible device may fuse to cut off the current in the leg where it is located, thereby protecting the leg from overcurrent damage. However, if an open circuit occurs in one or more of the legs, the magnetic field and electric field generated by the RF coil will change. A change in the magnetic field or electric field may result in poor imaging by the magnetic resonance system or damage to the health of the examination subject; this is explained further below with reference to FIGS. 1A-2B.

FIGS. 1A and 1B illustrate a magnetic field strength map obtained by subjecting an RF coil to simulated calculation in the related art. FIGS. 2A and 2B illustrate an electric field strength map obtained by subjecting an RF coil to simulated calculation in the related art. FIGS. 1A and 2A respectively simulate magnetic field strength and electric field strength of the RF coil when operating in a normal state (e.g. the fusible devices on all of the legs are normally connected, and not fused). FIGS. 1B and 2B respectively simulate magnetic field strength and electric field strength of the RF coil when operating in an abnormal state (e.g. the fusible device on one of the legs has fused). As shown in FIG. 1A, the positions indicated by the numbers 1-8 are respectively 8 legs of a transmitting layer coil; an outer ring of the transmitting layer coil may be a body coil for causing electromagnetic induction in the transmitting layer coil. The distribution of magnetic field strength is substantially the same at the positions of the 8 legs 1-8 in FIG. 1A. Correspondingly, in the electric field strength map shown in FIG. 2A, the distribution of electric field strength is also substantially the same at the positions of the 8 legs. The uniformly distributed magnetic field and electric field will provide a foundation for good magnetic resonance imaging.

When, for example, the fusible device (e.g. resistance wire) on leg no. 1 fuses, the corresponding magnetic field strength and electric field strength are as shown in FIGS. 1B and 2B. It can be seen from FIG. 1B that fusing of the fusible device on leg no. 1 causes the magnetic field strength at the position corresponding to leg no. 1 to decrease, and this will result in a corresponding increase in current in a leg in the vicinity (e.g. leg no. 2), such that the magnetic field strength at the position corresponding to leg no. 2 increases. Such non-uniformity of electric field strength at the positions corresponding to leg no. 1 and leg no. 2 can also be seen in FIG. 2B. In these circumstances, continuing to perform a nuclear magnetic resonance scan and imaging will result in impaired final imaging quality. In addition, due to the non-uniform distribution of magnetic field and electric field, a higher transmission voltage is needed to produce a magnetic resonance RF field (also called B1 field) of the same size as that produced in the normal state at the central position of the RF coil (which is generally also the position where the region under examination is located). This will result in the examination subject receiving a higher RF power, causing the local SAR to exceed a safe threshold, and this might cause harm to the examination subject through overheating.

In view of this, the present disclosure provides a method and apparatus for monitoring an operating state of a birdcage coil in a magnetic resonance system, an electronic device, a magnetic resonance system, a birdcage coil for a magnetic resonance system, a computer readable storage medium and a computer program product.

Embodiments of the present disclosure are described in detail below with reference to the drawings.

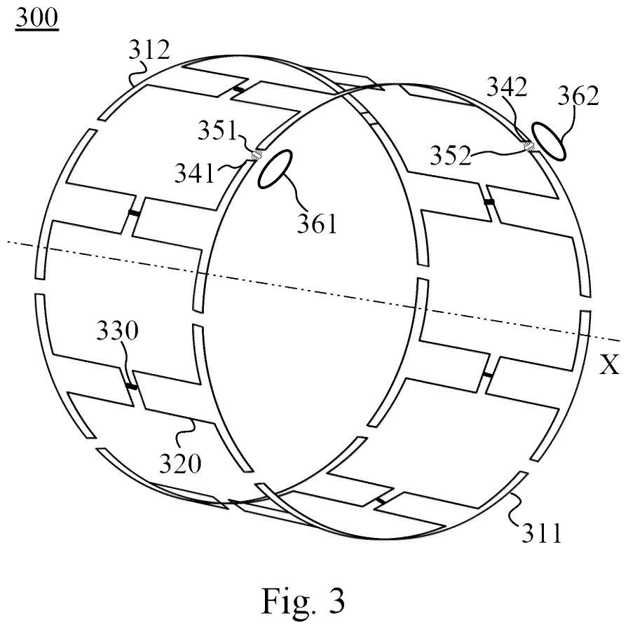

FIG. 3 illustrate a schematic drawing of a birdcage coil 300 in a magnetic resonance system according to an embodiment of the present disclosure. The birdcage coil 300 may be a local coil (e.g. a transmit/receive coil for the head or knee), a self-transmitting/self-receiving coil, or a transmitting layer coil in an inductive transmit/receive coil. The inductive transmit/receive coil may comprise a transmitting layer and a receiving layer; the transmitting layer may experience electromagnetic induction with a body coil in the magnetic resonance system, thereby generating a uniform, circularly polarized magnetic resonance RF field in the inductive transmit/receive coil. The receiving layer may collect magnetic resonance signal of the examination subject.

As shown in FIG. 3, the birdcage coil 300 comprises: a pair of end rings (specifically, a first end ring 311 and a second end ring 312); multiple legs 320 arranged between the first end ring 311 and second end ring 312 and connected to the pair of end rings (to avoid cluttering the drawing, only one of the legs is marked with the reference label 320); and a fusible device 330 arranged in each leg 320. In an example, the first end ring 311, the second end ring 312, and the multiple legs 320 connecting the pair of end rings, are all made of an electrically-conductive material (e.g. metal). The fusible device 330 may be a fuse; when the current in one of the legs 320 exceeds a permitted current value for the corresponding fusible device 330, the fusible device 330 may fuse (i.e. actuate, which may include the fuse “blowing,” e.g. opening) to cut off the current in the leg 320 where it is located, thereby protecting the leg 320.

It will be understood that although the birdcage coil 300 shown in FIG. 3 comprises 8 legs 320, the birdcage coil 300 may also comprise any suitable different number of legs, e.g. 12 legs, 16 legs, etc.

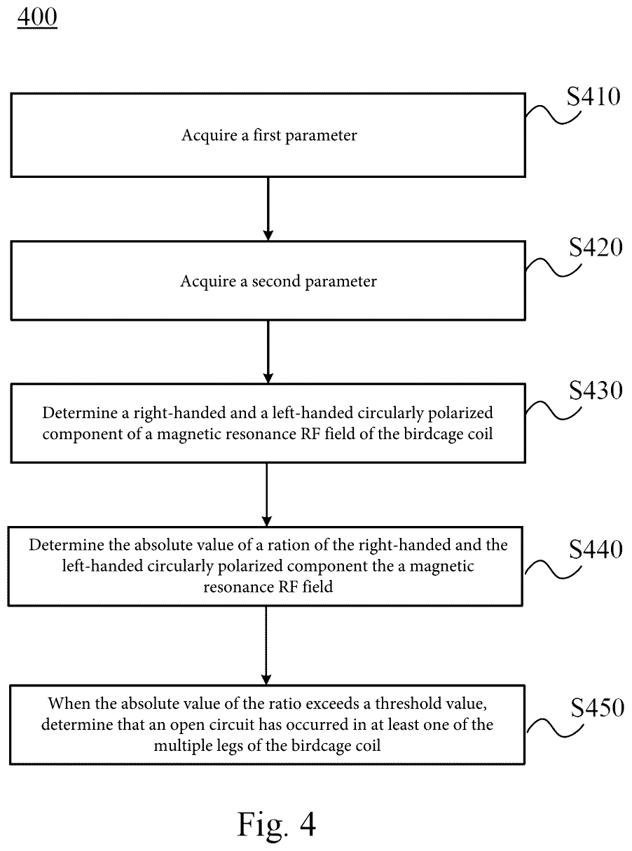

FIG. 4 shows a flow chart of a method 400 for monitoring an operating state of a birdcage coil in a magnetic resonance system according to an embodiment of the present disclosure. The method 400 may for example be applied to the birdcage coil 300 in a magnetic resonance system according to an embodiment of the present disclosure.

As shown in FIG. 4, the method 400 comprises:
block S410, acquiring a first parameter, the first parameter being associated with a voltage at a first position 341 of a first end ring 311 in a pair of end rings;
block S420, acquiring a second parameter, the second parameter being associated with a voltage at a second position 342 of the first end ring 311, the second position being different from the first position 341;
block S430, based on the first parameter and the second parameter, determining a right-handed circularly polarized component and a left-handed circularly polarized component of a magnetic resonance RF field of a birdcage coil 300;
block S440, determining the absolute value of the ratio of the left-handed circularly polarized component to the right-handed circularly polarized component; and
block 450, in response to determining that the absolute value of the ratio exceeds a threshold, determining that an open circuit has occurred in at least one of multiple legs 320.

The magnetic field generated by a magnetic resonance system comprises a static magnetic field and an RF field. The static magnetic field (also called B0 field, main magnetic field, or externally applied magnetic field) may be a magnetic field generated by a magnet disposed at a radially outer side of the RF coil; in the case of superconducting magnets currently used in clinical settings, the magnetic field strength thereof may be in the range of 0.2 T (Teslas) to 7.0 T, and is commonly 1.5 T or 3.0 T. When an examination subject enters the main magnetic field, hydrogen protons within the body experience Larmor precession, giving rise to a macroscopic magnetization vector in conformity with the direction of the main magnetic field. The RF field (also called B1 field) may be a magnetic field generated by RF pulses (a type of electromagnetic wave) as they propagate. The RF field may be perpendicular to the static magnetic field, and applied to the examination subject's body as pulses, thus causing hydrogen protons in the examination subject's body to produce magnetic resonance.

The variation with time of the path of the electric field of an RF pulse at a particular position during propagation may be referred to as polarization, and the path thus formed may include a linear, circular, or elliptical path. The three different types of path respectively correspond to three different types of polarization: linear polarization, circular polarization, and elliptical polarization. Circular polarization may include left-handed circular polarization and right-handed circular polarization. An RF coil in a normal operating state can produce a relatively uniform circularly-polarized RF field.

The embodiments as discussed herein leverage the discovery that when one or more legs in a birdcage coil experiences an open circuit fault (e.g. the fusible device in one or more legs fuses), the distribution of the magnetic field or electric field generated by an RF pulse will become non-uniform (as shown in FIGS. 1A-2B), and correspondingly, the circularly polarized state of the RF field is inferior to (i.e. less uniform than) the circularly polarized state of the RF field of the RF coil in the normal operating state. Thus, after acquiring the first parameter and second parameter (which may for example be voltage values or current values) respectively associated with the voltage at the first position 341 and second position 342 of the end ring 311, a right-handed circularly polarized component (also called B1+ or right-handed vector) and a left-handed circularly polarized component (also called 1− or left-handed vector) of the RF field of the birdcage coil 300 are determined on the basis of the first parameter and second parameter, and then the absolute value of the ratio of the left-handed circularly polarized component to the right-handed circularly polarized component is determined. The absolute value (which may be expressed as ‘k’ for example) of this ratio may be used to indicate the circularly polarized state of the RF field. In an example, a larger absolute value of the ratio means that the circularly polarized state of the RF field is worse; and a smaller absolute value of the ratio means that the circularly polarized state of the RF field is better. If the absolute value of the ratio is too large and exceeds a threshold, it can be determined that an open circuit has occurred in at least one of the multiple legs. Thus, during operation of the magnetic resonance system, the state of the multiple legs of the birdcage coil can be monitored by acquiring the first parameter and the second parameter in real time, so that an open circuit state in a leg of the birdcage coil can be discovered promptly. Based on a determined open circuit state in a leg of the birdcage coil, it is possible to further determine whether to pause the magnetic resonance scanning process, promptly adjust operating parameters of the magnetic resonance system, or, when imaging quality deteriorates, promptly and accurately determine the cause of the imaging deterioration so as to facilitate overhaul; in this way, the user experience is improved, and harm to the examination subject through overheating is reduced or avoided.

It will be understood that the first end ring 311 may comprise an end ring close to a front side of the magnetic resonance system (the side where the examination subject enters), or an end ring close to a rear side of the magnetic resonance system.

According to some embodiments, the first parameter may comprise a first voltage associated with the voltage at the first position 341, and the second parameter may comprise a second voltage associated with the voltage at the second position 342. Moreover, the right-handed circularly polarized component may be proportional to \sqrt{A₁e^{jφ}^{₁}−jA₂e^{jφ}^{₂}}, and the left-handed circularly polarized component may be proportional to \sqrt{A₁e^{jφ}^{₁}−jA₂e^{jφ}^{₂}}, wherein A₁ and φ₁ are respectively the amplitude and phase of the first voltage, and A₂ and φ₂ are respectively the amplitude and phase of the second voltage.

In an example, the right-handed circularly polarized component (B₁⁺) may be directly proportional to \sqrt{A₁e^{jφ}^{₁}−jA₂e^{jφ}^{₂}} and the left-handed circularly polarized component (B₁⁻) may be directly proportional to \sqrt{A₁e^{jφ}^{₁}−jA₂e^{jφ}^{₂}}.

For example, the right-handed circularly polarized component (B₁⁺) and \sqrt{A₁e^{jφ}^{₁}−jA₂e^{jφ}^{₂}} satisfy the following relationship:

$${{B}_{1}}^{+} {∝}^{\sqrt{{A}_{1} {e}^{j {φ}_{1}} - {jA}_{2} {e}^{j {φ}_{2}}}} . \qquad ( 1 )$$

The left-handed circularly polarized component (B₁⁻) and \sqrt{A₁e^{jφ}^{₁}−jA₂e^{jφ}^{₂}} may satisfy the following relationship:

$${{B}_{1}}^{-} {∝}^{\sqrt{{A}_{1} {e}^{j {φ}_{1}} + j {A}_{2} {e}^{j {φ}_{2}}}} . \qquad ( 2 )$$

Based on the proportional relationships above, the absolute value k of the ratio of the left-handed circularly polarized component (B₁⁻) to the right-handed circularly polarized component (B₁⁺) may be determined according to the following relationship:

$$k = \vert {B}_{{1}^{-}} / {B}_{{1}^{+}} \vert . \qquad ( 3 )$$

In an example, the first voltage and the second voltage obtained may be subjected to signal amplification in equal proportions, and the ratio of the left-handed circularly polarized component (B1−) to the right-handed circularly polarized component (B1+) may be separately calculated on the basis of the amplitude and phase of the amplified voltage.

According to some embodiments, with respect to a central axis X of the birdcage coil 300, the first position 341 and second position 342 are spread apart (i.e. disposed) at 90 degrees from each other.

For example, the first position 341 may be as shown in FIG. 3, located at the position of −45 degrees with respect to the central axis X of the birdcage coil 300 (assuming that the vertical direction is 0 degrees), and correspondingly, the second position 342 may be as shown in FIG. 3, located at the position of +45 degrees with respect to the central axis X of the birdcage coil 300. In addition, the first position 341 may be located at the position of +45 degrees with respect to the central axis X of the birdcage coil 300 (assuming that the vertical direction is 0 degrees), and correspondingly, the second position 342 may be located at the position of +135 degrees with respect to the central axis X of the birdcage coil 300.

The first position 341 and second position 342 may be at any angle with respect to the vertical direction, as long as the first position 341 and second position 342 are spread apart at 90 degrees from each other with respect to the central axis X of the birdcage coil 300. However, there is no limitation to this, and the angle may be changed appropriately as required.

According to some embodiments, further referring to FIG. 3, the first parameter may be associated with a voltage of a first capacitor 351 at the first end ring 311, and the second parameter may be associated with a voltage of a second capacitor 352 at the first end ring 311. In some RF coils, multiple capacitors may be arranged in the end rings; the capacitors may for example be used to form induction circuits together with inductors. An inductor has a higher instantaneous voltage than an end-ring conductor around it; correspondingly, an acquired voltage associated with a capacitor disposed at the end ring may also be greater, and more accurately reflect the corresponding voltage at the first position or second position. In this way, the accuracy of the determined right-handed circularly polarized component (B1+) and the left-handed circularly polarized component (B1−) may be further increased.

It will be understood that although only the first capacitor 351 and second capacitor 352 are shown in FIG. 3, the birdcage coil 300 could also comprise a greater number of capacitors; for example, each of a greater number of capacitors could be arranged at intervals on the first end ring 311 or second end ring 312.

According to some embodiments, further referring to FIG. 3, the first parameter may be measured by means of a first contactless probe 361 close to the first position 341; or the second parameter may be measured by means of a second contactless probe 362 close to the second position 342.

In an example, both the first parameter and second parameter may be measured by means of contactless probes disposed at corresponding positions.

By using contactless probes, the first parameter and second parameter can be measured without structurally modifying the RF coil. The contactless probes may for example use the principle of electromagnetic induction to subject the first position 341 and second position 342 to measurement.

The first contactless probe 361 and second contactless probe 362 may for example be annular probes as shown in FIG. 3. The plane in which the ring of the annular probe lies may be parallel to a tangential direction of the first position 341 or second position 342 in the end ring, and the annular probe may be aligned with the first position 341 or second position 342.

According to some examples, the birdcage coil 300 may be a transmitting layer coil in an inductive transmit/receive coil, the first parameter may be a first induced voltage measured by the first contactless probe 361, and the second parameter may be a second induced voltage measured by the second contactless probe 362.

The inductive transmit/receive coil may comprise a transmitting layer and a receiving layer; the transmitting layer may experience electromagnetic induction with a body coil in the magnetic resonance system, thereby generating a uniform, circularly polarized magnetic resonance RF field in the inductive transmit/receive coil.

In an example, the first contactless probe 361 may be aligned with the first capacitor 351 arranged at the first position 341, and thereby generate the first induced voltage; the second contactless probe 362 may be aligned with the second capacitor 352 arranged at the second position 342, and thereby generate the second induced voltage.

According to some embodiments, determining that an open circuit has occurred in at least one of the multiple legs 320 in block S450 above may comprise: determining that a fusible device on at least one of the multiple legs 320 has fused (i.e. actuated). The fusible device (e.g. fuse) is the part of the leg 320 that most easily forms an open circuit; therefore, when the absolute value (e.g. k) of the ratio determined exceeds a threshold (which may be preset according to the magnetic resonance system model or characteristics of a region of the examination subject), it is determined that the fusible device in the leg 320 has fused, so the cause of the open circuit can be determined quickly, thus facilitating overhaul/troubleshooting and the replacement of components (e.g. the fuse).

According to some embodiments, acquiring the first parameter in block S410 above may comprise: acquiring a forward voltage of a first channel and a reverse voltage of the first channel measured by a directional coupler in a transmission link of the birdcage coil; and based on the forward voltage of the first channel and the reverse voltage of the first channel, determining a voltage of the first capacitor as the first parameter, the voltage of the first capacitor being proportional to the weighted sum of the forward voltage of the first channel and the reverse voltage of the first channel.

Furthermore, acquiring the second parameter in block S420 above may comprise: acquiring a forward voltage of a second channel and a reverse voltage of the second channel measured by a directional coupler; and based on the forward voltage of the second channel and the reverse voltage of the second channel, determining a voltage of the second capacitor as the second parameter, the voltage of the second capacitor being proportional to the weighted sum of the forward voltage of the second channel and the reverse voltage of the second channel.

For example, in the case of a local coil (e.g. a transmit/receive coil for the head or knee), a directional coupler (e.g. a narrowband directional coupler) arranged in a transmission link is used to measure a forward voltage and a reverse voltage in the transmission link. Moreover, by separately measuring forward voltages and reverse voltages of different channels in the birdcage coil, the voltage of the capacitor on the end ring corresponding to each channel can be separately determined.

For example, a voltage U1 of the first capacitor, a forward voltage S_{1_FWD}, and a reverse voltage S_{1_REF} of the corresponding first channel, may satisfy the following relationship:

$$U 1 ∝ A \cdot {S}_{1 \_ FWD} + B \cdot {S}_{1 \_ REF} ; \qquad ( 4 )$$

and a voltage U2 of the second capacitor, a forward voltage S_{2_FWD}, and a reverse voltage S_{2_REF} of the corresponding second channel, may satisfy the following relationship:

$$U 2 ∝ A \cdot {S}_{2 \_ FWD} + B \cdot {S}_{2 \_ REF} , \qquad ( 5 )$$

where A and B may represent constants related to characteristics of the RF coil itself or the magnetic resonance system.

By measuring the forward voltages and reverse voltages of any two channels, the corresponding voltage U1 of the first capacitor and voltage U2 of the second capacitor are respectively obtained. U1 and U2 may each have an amplitude (for example, the amplitude of U1 is M₁, and the amplitude of U2 is M₂) and a phase (for example, the phase of U1 is Θ₁, and the phase of U2 is Θ₂); next, a right-handed circularly polarized component (B₁⁺) and a left-handed circularly polarized component (B₁⁻) may be determined according to the following relationships:

For example, the right-handed circularly polarized component (B₁⁺), and the amplitude and phase of the voltage U1 of the first capacitor and the voltage U2 of the second capacitor, satisfy the following relationship:

$${{B}_{1}}^{+} {∝}^{\sqrt{{M}_{1} {e}^{j {θ}_{1}} + {jM}_{2} {e}^{j {θ}_{2}}}} ; \qquad ( 6 )$$

and the left-handed circularly polarized component (B₁⁻), and the amplitude and phase of the voltage U1 of the first capacitor and the voltage U2 of the second capacitor, satisfy the following relationship:

$${{B}_{1}}^{-} {∝}^{\sqrt{{M}_{1} {e}^{j {θ}_{1}} + {jM}_{2} {e}^{j {θ}_{2}}} .} \qquad ( 7 )$$

It will be understood that the abovementioned first channel and second channel may be any two channels in a multi-channel coil.

According to another aspect of the present disclosure, an apparatus for monitoring an operating state of a birdcage coil in a magnetic resonance system is provided. The birdcage coil comprises a pair of end rings, and multiple legs arranged between the pair of end rings and connected to the pair of end rings.

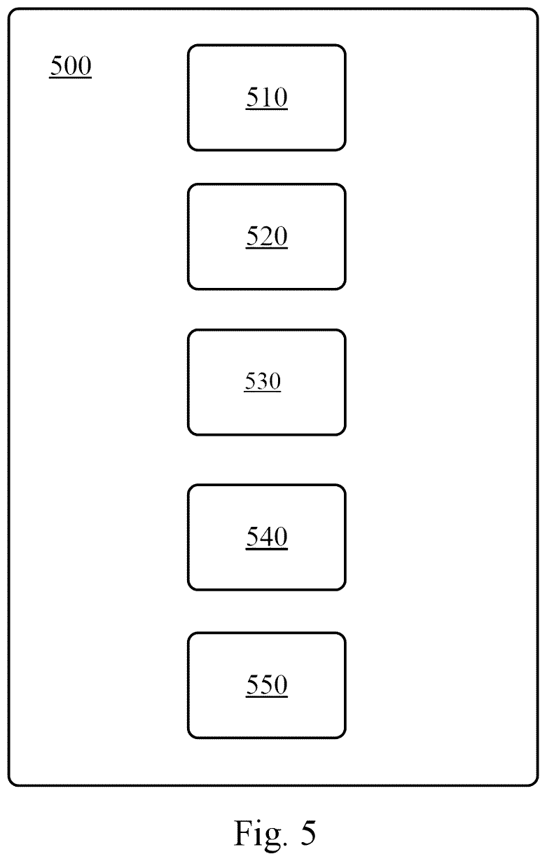

FIG. 5 shows a structural block diagram of an apparatus 500 for monitoring an operating state of a birdcage coil in a magnetic resonance system according to an embodiment of the present disclosure. As shown in FIG. 5, the apparatus 500 comprises:
a first parameter acquisition unit 510 configured to acquire a first parameter, the first parameter being associated with a voltage at a first position of a first end ring in the pair of end rings;
a second parameter acquisition unit 520 configured to acquire a second parameter, the second parameter being associated with a voltage at a second position of the first end ring, the second position being different from the first position;
a magnetic resonance RF field determining unit 530 configured to determine, on the basis of the first parameter and the second parameter, a right-handed circularly polarized component and a left-handed circularly polarized component of a magnetic resonance RF field of the birdcage coil;
a ratio determining unit 540 configured to determine the absolute value of the ratio of the left-handed circularly polarized component to the right-handed circularly polarized component; and
an open circuit determining unit 550 configured to determine, in response to determining that the absolute value of the ratio exceeds a threshold, that an open circuit has occurred in at least one of the multiple legs.

It should be understood that the units of the apparatus 500 shown in FIG. 5 may correspond to the blocks in the method 400 described with reference to FIG. 4. Thus, the operations, features and advantages described above in relation to the method 400 likewise apply to the apparatus 500 and the units comprised therein. For conciseness, some operations, features and advantages are not described again here.

According to another aspect of the present disclosure, an electronic device is provided, comprising: at least one processor; and a memory in communicative connection with the at least one processor. The memory stores instructions which are executable by the at least one processor; the instructions are executed by the at least one processor, to enable the at least one processor to perform the method for monitoring an operating state of a birdcage coil in a magnetic resonance system according to an embodiment of the present disclosure.

According to another aspect of the present disclosure, a birdcage coil for a magnetic resonance system is provided. Referring to FIG. 3, the birdcage coil 300 comprises:
a pair of end rings 311, 312, and multiple legs 320 arranged between the pair of end rings and connected to the pair of end rings;
a first contactless probe 361 arranged close to a first capacitor 351 on a first end ring 311 in the pair of end rings, for generating a first induced voltage under the action of the first capacitor 351; and
a second contactless probe 362 arranged close to a second capacitor 352 on the first end ring 311, for generating a second induced voltage under the action of the second capacitor 352.

According to some embodiments, with respect to a central axis X of the birdcage coil 300, the first contactless probe 361 and second contactless probe 362 are spread apart at 90 degrees from each other.

According to some embodiments, the birdcage coil may be an inductive transmit/receive coil, a self-transmitting/self-receiving coil or a local coil.

In an example, the first contactless probe 361 and second contactless probe 362 may for example be annular probes as shown in FIG. 3. The plane in which the ring of the annular probe lies may be parallel to a tangential direction of the first position 341 or second position 342 in the end ring, and the annular probe may be aligned with the first position 341 or second position 342.

According to another aspect of the present disclosure, referring to FIG. 3, a magnetic resonance system is provided, comprising: a birdcage coil 300, the birdcage coil 300 comprising a pair of end rings 311, 312, and multiple legs 320 arranged between the pair of end rings and connected to the pair of end rings; and the abovementioned electronic device or the apparatus 500 for monitoring an operating state of a birdcage coil in a magnetic resonance system according to an embodiment of the present disclosure.

According to some embodiments, the magnetic resonance system may further comprise:
a first contactless probe 361 arranged close to a first capacitor 351 on a first end ring 311 in the pair of end rings 311, 312, for generating an induced voltage at the first capacitor 351; and
a second contactless probe 362 arranged close to a second capacitor 352 on the first end ring 311, for generating an induced voltage at the second capacitor 352.

According to some embodiments, with respect to a central axis X of the birdcage coil 300, the first contactless probe 361 and second contactless probe 362 may be spread apart at 90 degrees from each other.

It will be understood that the magnetic resonance system according to embodiments of the present disclosure may further comprise a magnet, a gradient system and a computer system, etc., which are not shown in the drawings.

According to another aspect of the present disclosure, a non-transitory computer readable storage medium storing a computer program is provided, wherein the computer program, when executed by a processor, realizes the method for monitoring an operating state of a birdcage coil in a magnetic resonance system according to an embodiment of the present disclosure.

According to another aspect of the present disclosure, a computer program product is provided, comprising a computer program, wherein the computer program, when executed by a processor, realizes the method for monitoring an operating state of a birdcage coil in a magnetic resonance system according to an embodiment of the present disclosure.

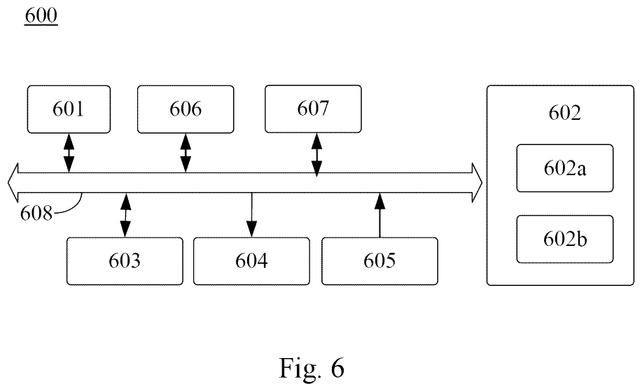

FIG. 6 is a block diagram showing an example of an electronic device 600 according to an exemplary embodiment of the present disclosure. It must be explained that the structure shown in FIG. 6 is merely an example; depending on the specific manner of implementation, the electronic device of the present disclosure may only comprise one or more of the constituent parts shown in FIG. 6.

The electronic device 600 may for example be a general-purpose computer (e.g. a laptop computer, a tablet computer, or various other types of computer), a mobile phone, or a personal digital assistant. According to some embodiments, the electronic device 600 may be a cloud computing device and a smart device. According to some embodiments, the electronic device 600 may be a magnetic resonance scan imaging device.

According to some embodiments, the electronic device 600 may be configured to subject an image, etc. to processing, and transmit a result of the processing to an output device, so that it is provided to a user. The output device may for example be a display screen, a device comprising a display screen, or another output device. For example, the electronic device 600 may be configured to subject the image to target detection, and transmit a result of target detection to a display device for display; the electronic device 600 may also be configured to subject the image to enhancement processing, and transmit a result of enhancement to a display device for display.

The electronic device 600 may comprise an image processing circuit 603; the image processing circuit 603 may be configured to subject the image to various types of image processing. The image processing circuit 603 may for example be configured to subject the image to at least one of the following types of image processing: noise reduction, geometric correction, feature extraction, detection and/or identification of objects in the image, and enhancement processing. The image processing circuit 603 may use custom hardware, and/or may be realized using hardware, software, firmware, middleware, microcode, hardware description language or any combination thereof. For example, one or more of the various circuits mentioned above may be realized by using assembly language or hardware programming language (such as VERILOG, VHDL, C++) to program hardware (e.g. a programmable logic circuit comprising a field programmable gate array (FPGA) and/or a programmable logic array (PLA)), using logic and algorithms according to the present disclosure.

According to some embodiments, the electronic device 600 may further comprise an output device 604; the output device 604 may be any type of device used to present information, and may include, but is not limited to, a display screen, a terminal with display functionality, earphones, a loudspeaker, a vibrator and/or a printer, etc.

According to some embodiments, the electronic device 600 may further comprise an input device 605; the input device 605 may be any type of device for inputting information to the electronic device 600, and may include, but is not limited to, various types of sensor, mouse, keyboard, touch screen, push button, control stick, microphone and/or remote controller, etc.

According to some embodiments, the electronic device 600 may further comprise a communication device 606; the communication device 606 may be any type of device or system enabling communication with an external device and/or with a network, and may include, but is not limited to, a modem, a network card, an infrared communication device, a wireless communication device and/or a chipset, e.g. a Bluetooth device, a 802.11 device, a WiFi device, a WiMax device, a cellular communication device and/or similar.

According to some embodiments, the electronic device 600 may further comprise a processor 601. The processor 601 may be any type of processor, and may include, but is not limited to, one or more general-purpose processor and/or one or more dedicated processor (e.g. special processing chip). The processor 601 may for example be, but is not limited to being, a central processing unit (CPU), a graphics processing unit (CPU), or various types of dedicated artificial intelligence (AI) computing chips, etc.

The electronic device 600 may further comprise a working memory 602 and a storage device 607. The processor 601 may be configured to be able to acquire and execute computer-readable instructions stored in the working memory 602, the storage device 607 or another computer-readable medium, such as program code of an operating system 602a, program code of an application program 602b, etc. The working memory 602 and storage device 607 are examples of computer-readable storage media used to store instructions, and the stored instructions may be executed by the processor 601 to implement the various functions described above. The working memory 602 may comprise both a volatile memory and a non-volatile memory (e.g. RAM, ROM, etc.). The storage device 607 may comprise a hard disk drive, solid state drive, removable media, including external and removable drives, memory cards, flash memory, floppy disks, optical disks (e.g. CD, DVD), storage arrays, network attached storage, storage area networks, etc. The working memory 602 and storage device 607 may both be collectively referred to as memory or computer-readable storage media herein, and may be non-transitory media capable of storing computer-readable, processor-executable program instructions as computer program code, which may be executed by the processor 601 as a specific device configured to implement the operations and functions described in the examples herein.

According to some embodiments, the processor 601 may perform control and scheduling of at least one of the image processing circuit 603 and various other apparatuses and circuits comprised in the electronic device 600. According to some embodiments, at least some of the constituent parts shown in FIG. 6 may be connected to and/or communicate with each other via a bus 608.

Software elements (programs) may be located in the working memory 602, including but not limited to an operating system 602a, one or more application program 602b, a driver and/or other data and code.

According to some embodiments, instructions for performing the abovementioned control and scheduling may be comprised in the operating system 602a or one or more application program 602b.

According to some embodiments, instructions for executing the method blocks of the present disclosure may be included in the one or more application program 602b, and the modules of the electronic device 600 mentioned above may be realized by the processor 601 reading and executing the instructions of the one or more application program 602b. In other words, the electronic device 600 may comprise the processor 601 and a memory storing a program (e.g. the working memory 602 and/or storage device 607), the program comprising instructions which, when executed by the processor 601, cause the processor 601 to perform the method according to various embodiments of the present disclosure.

According to some embodiments, some or all of the operations performed by the image processing circuit 603 may be realized by the processor 601 reading and executing the instructions of the one or more application program 602b.

Executable code or source code of instructions of software elements (programs) may be stored in a non-transitory computer-readable storage medium (e.g. the storage device 607), and when executed, may be stored in the working memory 602 (possibly compiled and/or installed). Thus, the present disclosure provides a computer-readable storage medium storing a program, the program comprising instructions which, when executed by a processor of an electronic device, cause the electronic device to perform the method according to various embodiments of the present disclosure. According to another embodiment, executable code or source code of instructions of software elements (programs) may also be downloaded from a remote location.

It should also be understood that various changes in form may be carried out according to particular requirements. For example, it is also possible to use custom hardware, and/or it is possible to use hardware, software, firmware, middleware, microcode, hardware description language or any combination thereof to realize each circuit, unit, module or element. For example, some or all of the circuits, units, modules or elements contained in the disclosed methods and devices may be realized by using assembly language or hardware programming language (such as VERILOG, VHDL, C++) to program hardware (e.g. a programmable logic circuit comprising a field programmable gate array (FPGA) and/or a programmable logic array (PLA)), using logic and algorithms according to the present disclosure.

According to some embodiments, the processor 601 in the electronic device 600 may be distributed on a network. For example, one processor may be used to perform some processing, and at the same time, other processing may be performed by another processor remote from said one processor. Other modules of the electronic device 600 may also be similarly distributed. Thus, the electronic device 600 may be interpreted as being a distributed computing system that performs processing at multiple locations. The processor 601 of the electronic device 600 may also be a processor of a cloud computing system, or a processor integrated with a blockchain.

Although embodiments or examples of the present disclosure have already been described with reference to the drawings, it should be understood that the abovementioned methods, systems and devices are merely exemplary embodiments or examples, and the scope of the present disclosure is not limited by these embodiments or examples, instead being defined solely by the granted claims and the equivalent scope thereof. Various key elements in the embodiments or examples may be omitted or may be replaced by equivalent key elements thereof. In addition, the blocks may be executed in an order different from that described in the present disclosure. Furthermore, various key elements in the embodiments or examples may be combined in various ways. Importantly, as technology evolves, many key elements described here may be replaced by equivalent key elements appearing after the present disclosure.

The various components described herein may be referred to as “units.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units, as applicable and relevant, may alternatively be referred to herein as “assemblies,” “circuitry,” “controllers,” “processors,” or “processing circuitry,” or alternatively as noted herein.

What is claimed is:

1. A method for monitoring an operating state of a birdcage coil in a magnetic resonance system, the birdcage coil comprising a pair of end rings and multiple legs arranged between and connected to the pair of end rings, the method comprising:
acquiring a first parameter associated with a first voltage at a first position of a first end ring of the pair of end rings;
acquiring a second parameter associated with a second voltage at a second position of the first end ring, the second position being different from the first position;
determining, based on the first parameter and the second parameter, a right-handed circularly polarized component and a left-handed circularly polarized component of a magnetic resonance radio frequency (RF) field of the birdcage coil;
determining an absolute value of a ratio of the left-handed circularly polarized component to the right-handed circularly polarized component; and
determining, in response to the absolute value of the ratio exceeding a threshold value, that an open circuit has occurred in at least one of the multiple legs.

2. The method as claimed in claim 1, wherein:
the first parameter comprises the first voltage, and the second parameter comprises the second voltage,
the right-handed circularly polarized component is proportional to \sqrt{A₁e^{jφ}^{₁}−jA₂e^{jφ}^{₂}},
the left-handed circularly polarized component is proportional to \sqrt{A₁e^{jφ}^{₁}−jA₂e^{jφ}^{₂}},
A₁ and φ₁ represent an amplitude and phase, respectively, of the first voltage, and
A₂ and φ₂ are represent an amplitude and phase, respectively, of the second voltage.

3. The method as claimed in claim 1, wherein the first position and the second position of the first end ring are disposed 90 degrees apart from one other with respect to a central axis of the birdcage coil.

4. The method as claimed in claim 1, wherein the first voltage comprises a voltage of a first capacitor at the first end ring, and
wherein the second voltage comprises a voltage of a second capacitor at the first end ring.

5. The method as claimed in claim 1, further comprising:
measuring the first voltage via a first contactless probe proximate to the first position; and
measuring the second voltage via a second contactless probe proximate to the second position.

6. The method as claimed in claim 5, wherein:
the birdcage coil comprises a transmitting layer coil in an inductive transmit/receive coil,
the first voltage comprises a first induced voltage, and
the second voltage comprises a second induced voltage.

7. The method as claimed in claim 1, wherein the determining that an open circuit has occurred in at least one of the multiple legs comprises determining that a fusible device on at least one of the multiple legs has actuated.

8. The method as claimed in claim 4, wherein the acquiring the first parameter comprises:
acquiring a forward voltage of a first channel and a reverse voltage of the first channel via a directional coupler in a transmission link of the birdcage coil; and
determining, based on the forward voltage of the first channel and the reverse voltage of the first channel, the voltage of the first capacitor as the first parameter,
wherein the voltage of the first capacitor is proportional to a weighted sum of the forward voltage of the first channel and the reverse voltage of the first channel.

9. The method as claimed in claim 8, wherein acquiring the second parameter comprises:
acquiring a forward voltage of a second channel and a reverse voltage of the second channel measured by the directional coupler; and
determining, based on the forward voltage of the second channel and the reverse voltage of the second channel, the voltage of the second capacitor as the second parameter,
wherein the voltage of the second capacitor is proportional to a weighted sum of the forward voltage of the second channel and the reverse voltage of the second channel.

10. A magnetic resonance system, comprising:
a birdcage coil comprising a pair of end rings and multiple legs arranged between and connected to the pair of end rings; and
processing circuitry configured to:
acquire a first parameter associated with a first voltage at a first position of a first end ring of the pair of end rings;
acquire a second parameter associated with a second voltage at a second position of the first end ring, the second position being different from the first position;
determine, based upon the first parameter and the second parameter, a right-handed circularly polarized component and a left-handed circularly polarized component of a magnetic resonance radio frequency (RF) field of the birdcage coil;
determine an absolute value of a ratio of the left-handed circularly polarized component to the right-handed circularly polarized component; and
determine, in response to determining that the absolute value of the ratio exceeds a threshold, that an open circuit has occurred in at least one of the multiple legs.

11. The magnetic resonance system as claimed in claim 10, wherein the magnetic resonance system further comprises:
a first contactless probe arranged proximate to a first capacitor on a first end ring of the pair of end rings, the first contactless probe configured to generate a first induced voltage via the first capacitor; and
a second contactless probe arranged proximate to a second capacitor on the first end ring the second contactless probe configured to generate a second induced voltage via the second capacitor.

12. The magnetic resonance system as claimed in claim 11, wherein the first contactless probe and the second contactless probe are disposed 90 degrees apart from one other with respect to a central axis of the birdcage coil.

13. A birdcage coil for a magnetic resonance system, comprising:
a pair of end rings and multiple legs arranged between and connected to the pair of end rings;
a first contactless probe arranged proximate to a first capacitor on a first end ring of the pair of end rings, the first contactless probe configured to generate a first induced voltage via of the first capacitor; and
a second contactless probe arranged proximate to a second capacitor on the first end ring, the second contactless probe configured to generate a second induced voltage via the second capacitor.

14. The birdcage coil as claimed in claim 13, wherein the first contactless probe and the second contactless probe are disposed at 90 degrees apart from one other with respect to a central axis of the birdcage coil.

15. The birdcage coil as claimed in claim 13, wherein the birdcage coil comprises an inductive transmit/receive coil, a self-transmitting/self-receiving coil, or a local coil.

16. A non-transitory computer-readable medium, comprising a computer program stored thereon that, when executed by a processor associated with a magnetic resonance system, causes the magnetic resonance system to monitor an operating state of a birdcage coil in the magnetic resonance system, the birdcage coil comprising a pair of end rings, and multiple legs arranged between and connected to the pair of end rings, the monitoring being performed by:
acquiring a first parameter associated with a first voltage at a first position of a first end ring of the pair of end rings;
acquiring a second parameter associated with a second voltage at a second position of the first end ring, the second position being different from the first position;
determining, based on the first parameter and the second parameter, a right-handed circularly polarized component and a left-handed circularly polarized component of a magnetic resonance radio frequency (RF) field of the birdcage coil;
determining an absolute value of a ratio of the left-handed circularly polarized component to the right-handed circularly polarized component; and
determining, in response to the absolute value of the ratio exceeding a threshold value, that an open circuit has occurred in at least one of the multiple legs.
